(19) United States
(12) Patent Application Publication
(10) Pub. No.: US 2026/0321944 A1
(43) Pub. Date: Oct. 15, 2026

(54) HIGH-FREQUENCY CIRCUIT AND SEMICONDUCTOR DEVICE

(71) Applicant: Mitsubishi Electric Corporation, Tokyo (JP)

(72) Inventor: Shin CHAKI, Tokyo (JP)

(73) Assignee: Mitsubishi Electric Corporation, Tokyo (JP)

(21) Appl. No.: 19/108,611

(22) PCT Filed: Nov. 7, 2022
(86) PCT No.: PCT/JP2022/041422

§ 371 Date: Mar. 4, 2025

(51) Int. Cl. H01P 1/04

(52) U.S. Cl. CPC H01P 1/04

(57) ABSTRACT

A high-frequency circuit according to the disclosure includes a substrate; and a signal line provided on an upper surface of the substrate, wherein first protrusions are formed at least along two facing sides of the substrate in a peripheral portion on a rear surface opposite to the upper surface of the substrate.

### FIELD

The present disclosure relates to a high-frequency circuit and a semiconductor device.

### BACKGROUND

PTL 1 discloses a filter in which a microstrip line is formed. This filter includes a dielectric substrate, a microstrip conductor metal film formed on a surface of the dielectric substrate, and a backside metal film formed over the entire surface on a rear surface of the dielectric substrate. At a position immediately below the microstrip conductor metal film inside the dielectric substrate, a plurality of internal spaces are formed at predetermined intervals along an extending direction of the microstrip conductor metal film.

### Citation List

### Patent Literature

[PTL 1] JP 2001-320202 A

### SUMMARY

### Technical Problem

As one method for making a circuit smaller in a microwave/millimeter-wave circuit, there is a method in which a substrate is made thinner. In a case where a substrate is made thinner, for example, from 100 μm to 50 μm for an MMIC using a microstrip line in impedance matching, a width of the microstrip line on an upper surface of a chip can be made smaller for the same characteristic impedance. It is therefore possible to reduce an area occupied by a matching circuit.

However, for example, in a case where a chip with a substrate that is made thinner from 100 μm to 50 μm is mounted with a conductive resin, the conductive resin may crawl up to an upper surface of the chip. Thus, there is a possibility that it becomes difficult to perform mounting with a high yield ratio. Further, there is a possibility that a function of the chip cannot be implemented as a result of unintentional short circuit of a pattern due to the conductive resin that has crawled up to the upper surface of the chip. Still further, as a result of the conductive resin adhering to a pad, there is a case where a problem that sufficient wire bonding strength cannot be obtained, or the like, may occur.

The present disclosure is directed to providing a high-frequency circuit and a semiconductor device capable of preventing crawling up of a joint material to an upper surface of a substrate.

### Solution to Problem

A high-frequency circuit according to the disclosure includes a substrate; and a signal line provided on an upper surface of the substrate, wherein first protrusions are formed at least along two facing sides of the substrate in a peripheral portion on a rear surface opposite to the upper surface of the substrate.

### Advantageous Effects of Invention

In the high-frequency circuit according to the present disclosure, when the high-frequency circuit is mounted using a joint material, a distance from a surface on which the joint material is applied to the upper surface of the substrate can be increased by the first protrusions. It is therefore possible to prevent crawling up of the joint material to the upper surface of the substrate.

### BRIEF DESCRIPTION OF DRAWINGS

FIG. 1 is a cross-sectional view of a high-frequency circuit according to a first embodiment.

FIG. 2 is a view for explaining a configuration on a rear surface side of the high-frequency circuit according to the first embodiment.

FIG. 3 is a cross-sectional view of a high-frequency circuit according to a first comparative example.

FIG. 4 is a cross-sectional view of a high-frequency circuit according to a second comparative example.

FIG. 5 is a perspective view for explaining a configuration of a semiconductor device according to the first embodiment.

FIG. 6 is a side view of the semiconductor device according to the first embodiment.

FIG. 7 is a perspective view for explaining a configuration of a wafer according to the first embodiment.

FIG. 8 is a view for explaining a state of the protrusion of the wafer according to the first embodiment before dicing.

FIG. 9 is a view for explaining a state of the protrusion of the wafer according to the first embodiment after dicing.

FIG. 10 is a cross-sectional view of a high-frequency circuit according to a second embodiment.

FIG. 11 is a view for explaining a configuration on a rear surface side of the high-frequency circuit according to the second embodiment.

FIG. 12 is a perspective view for explaining a configuration of a semiconductor device according to the second embodiment.

FIG. 13 is a side view of the semiconductor device according to the second embodiment.

FIG. 14 is a cross-sectional view of a high-frequency circuit according to a third embodiment.

FIG. 15 is a view for explaining a configuration on a rear surface side of the high-frequency circuit according to the third embodiment.

FIG. 16 is an enlarged view of a high-frequency circuit according to a fourth embodiment.

FIG. 17 is an enlarged view of a high-frequency circuit according to a fifth embodiment.

FIG. 18 is a view for explaining a configuration on a rear surface side of a high-frequency circuit according to a sixth embodiment.

FIG. 19 is a view for explaining a configuration on a rear surface side of a high-frequency circuit according to a modification of the sixth embodiment.

FIG. 20 is a cross-sectional view of a high-frequency circuit according to a seventh embodiment.

FIG. 21 is a view for explaining a configuration on a rear surface side of the high-frequency circuit according to the seventh embodiment.

### DESCRIPTION OF EMBODIMENTS

A high-frequency circuit and a semiconductor device according to each embodiment are described with reference to drawings. Identical or corresponding constitutional elements are given the same reference numerals, and the repeated description of such constitutional elements may be omitted.

### First Embodiment

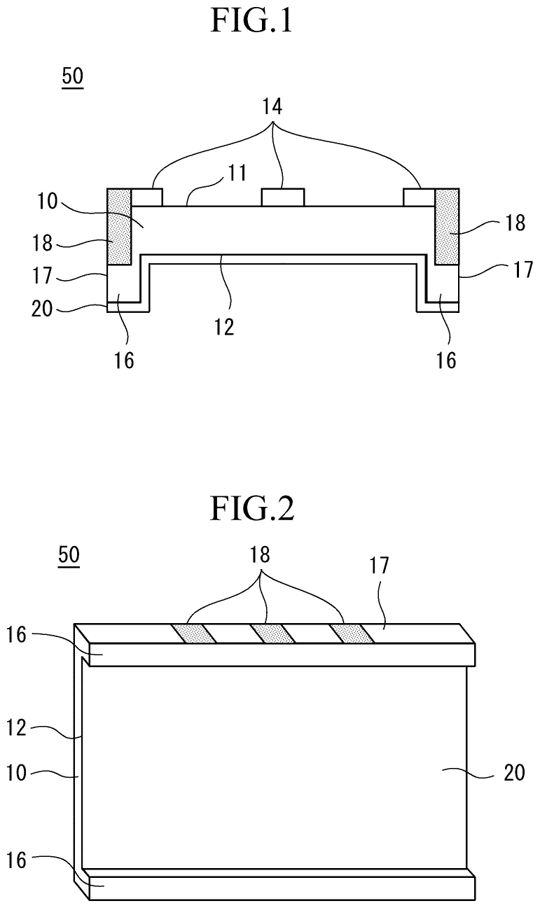

FIG. 1 is a cross-sectional view of a high-frequency circuit 50 according to a first embodiment. FIG. 2 is a view for explaining a configuration on a rear surface side of the high-frequency circuit 50 according to the first embodiment. The high-frequency circuit 50 is a microwave/millimeter-wave monolithic microwave integrated circuit (MMIC) chip. The high-frequency circuit 50 includes a substrate 10, and a signal line 14 provided on an upper surface 11 of the substrate 10. The substrate 10 is, for example, a SiC substrate. The signal line constitutes, for example, a microstrip line.

In a peripheral portion on a rear surface 12 opposite to the upper surface 11 of the substrate 10, protrusions 16 are formed along two facing sides of the substrate 10. In other words, the substrate 10 is made thinner while leaving only portions along the two facing sides that are circumferential portions of the circuit. In the present embodiment, in the peripheral portion on the rear surface 12 of the substrate 10, protrusions are not formed along two sides other than the two sides along which the protrusions 16 are formed.

A length of one side of the high-frequency circuit 50 is, for example, equal to or less than 5 mm. A thickness of a thick portion of the substrate 10 is, for example, 100 μm to 200 μm. A thickness of a portion that is made thinner of the substrate 10 is, for example, equal to or less than 50 μm and specifically 10 μm to 50 μm. A width of the protrusion 16 is, for example, approximately 50 to 200 μm.

On side surfaces 17 of the substrate 10 corresponding to the two sides on which the protrusions 16 are formed, pads 18 are provided. The pads 18 are DC or RF pads. Further, the rear surface 12 of the substrate 10 is covered with a conductor layer 20 that becomes a GND.

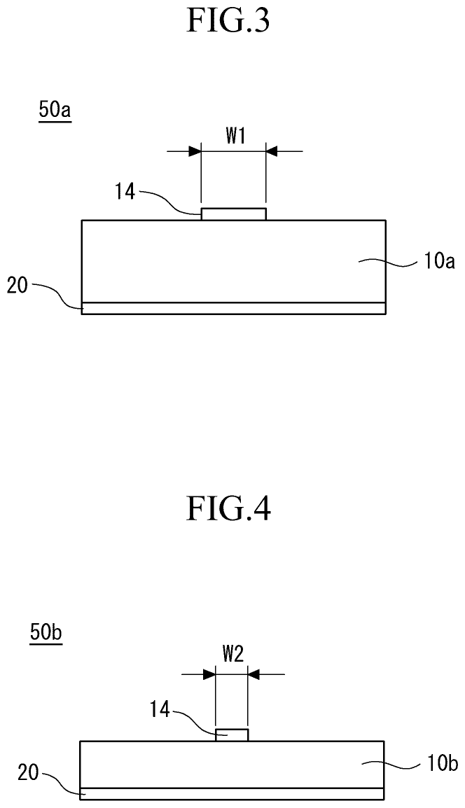

FIG. 3 is a cross-sectional view of a high-frequency circuit 50a according to a first comparative example. FIG. 4 is a cross-sectional view of a high-frequency circuit 50b according to a second comparative example. Reduction in size of the circuit by making the substrate thinner will be described using FIGS. 3 and 4. A thickness of a substrate 10a of the high-frequency circuit 50a is 100 μm. The signal line 14 is provided on an upper surface of the substrate 10a. The conductor layer 20 that becomes a GND is provided on a rear surface of the substrate 10a. In contrast, a thickness of a substrate 10b of the high-frequency circuit 50b is 50 μm. The signal line 14 is provided on an upper surface of the substrate 10b. The conductor layer 20 that becomes a GND is provided on a rear surface of the substrate 10b.

If the high-frequency circuits 50a and 50b have the same characteristic impedance, a width of the signal line 14 becomes smaller in the high-frequency circuit 50b with a thinner substrate 10b, and W1>W2. For example, as an output synthesis circuit in a final stage of a power amplifier, typically, a low-impedance line is used. If a line width of a matching circuit can be made smaller for the same characteristic impedance, an area of the output synthesis circuit can be made smaller. It is therefore possible to achieve reduction in size of the MMIC as a whole.

However, for example, in a case where a GaN MMIC chip using a SiC substrate that is made thinner to 50 μm is mounted with a conductive resin, the conductive resin may crawl up to an upper surface of the chip. In the high-frequency circuit 50b, a distance from the rear surface 12 on which the conductive resin is provided, to the upper surface 11 is shortened from 100 μm to 50 μm. In this event, when side surfaces of the MMIC chip are grasped with tweezers, a collet, or the like, a distal end portion of the tweezers, the collet, or the like, approaches the surface on which the conductive resin is applied. As a result, the conductive resin is soaked up, which increases a risk of crawling up of the conductive resin to a pattern provided on the upper surface of the substrate 10. Thus, there is a possibility that mounting cannot be performed with a high yield ratio, and it becomes difficult to achieve stable production.

In contrast, in the present embodiment, a distance from the surface on which a joint material such as the conductive resin is applied to the upper surface 11 of the substrate 10 can be increased by the protrusions 16. By this means, by grasping two sides where the substrate 10 is thick upon mounting of the high-frequency circuit 50, it is possible to secure a distance from the distal end portion of the tweezers, the collet, or the like, to the surface on which the conductive resin is applied. It is therefore possible to prevent crawling up of the joint material to the upper surface 11 of the substrate 10 via the tweezers, the collet, or the like. As described above, in the present embodiment, it is possible to make the high-frequency circuit 50 smaller by making the substrate 10 thinner and mount the high-frequency circuit 50 with a high yield ratio.

Further, in the present embodiment, spread of the conductive resin can be confirmed from two sides of the substrate 10, on which the protrusions 16 are not formed. It is therefore possible to visually confirm that die bonding can be reliably performed. Further, by providing the DC or RF extraction pads 18 not on the upper surface 11 of the substrate 10 but on the side surfaces 17, it is possible to make the MMIC chip further smaller.

As other comparative examples of the present embodiment, to expand a selection range of low-impedance or high-impedance lines, there is a method in which a portion immediately under the microstrip line is made locally thinner. There is also a method in which a portion immediately below the microstrip line is filled with a material having different permittivity from permittivity of the substrate. In such a configuration, it is considered that the signal line branches into a plurality of lines like a T-branch structure or a cross-branch structure at a portion where characteristic impedance changes, specifically, a boundary, or the like, between a locally thinned portion and a thick portion of the substrate. In such a case, a parasitic component may be added, and it may become difficult to achieve performance in a terahertz-waveband circuit.

Thus, as in the present embodiment, it is desirable that a central portion of the substrate 10 in which the circuit is formed is uniformly made thinner. Note that in FIG. 1, part of the signal line 14 is positioned immediately above the protrusion 16. In a case where the signal line 14 immediately above the protrusion 16 is a line or a pad for applying a DC bias, change of the characteristic impedance of the signal line 14 typically less affects circuit characteristics. This is because an RF signal component to which attention is paid is appropriately processed within the circuit or in a peripheral circuit outside of the MMIC. In a case where the signal line 14 immediately above the protrusion 16 is a main line or an RF probe pad through which an RF signal passes, change of the characteristic impedance, that is, change of a distance between the signal line 14 and a GND conductor may affect the characteristics. Thus, there is a case where it is necessary to grasp in advance the influence through a simulation of an electromagnetic field, or the like, and make an appropriate design such as change of the width of the signal line. As described above, the protrusion 16 may be provided while avoiding a portion where the circuit is formed, particularly, the main line or the RF probe pad through which the RF signal passes. Further, the signal line 14 immediately above the protrusion 16 may be a line or a pad for applying a DC bias.

Further, by making the whole surface of the central portion of the substrate 10 thinner, heat dissipation of a transistor can be improved. Still further, by making the substrate 10 thinner, a diameter of a via hole (VH) can be made smaller, so that it becomes easy to make the circuit further smaller. The VH is normally engraved through dry etching. Thus, if an amount of engravement, that is, a thickness of the substrate is small, the diameter of the VH can be made smaller.

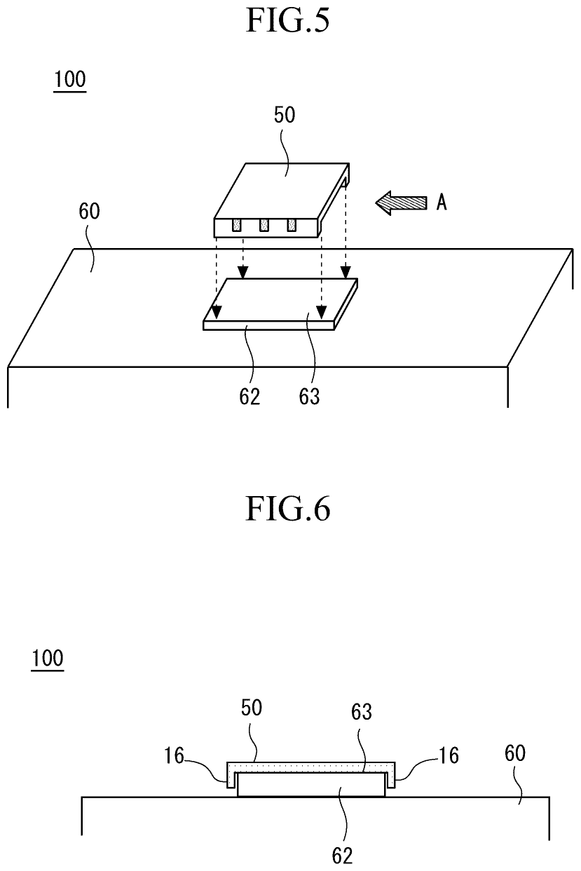

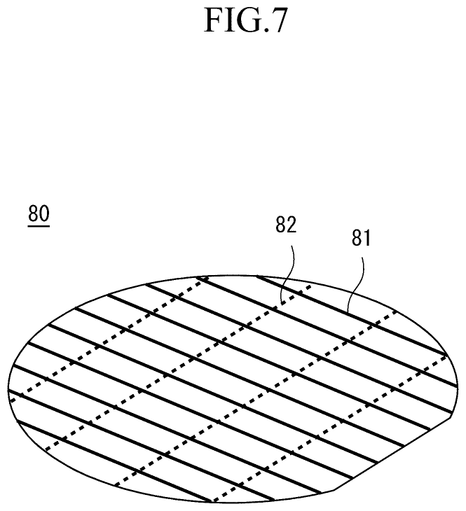

FIG. 5 is a perspective view for explaining a configuration of a semiconductor device 100 according to the first embodiment. FIG. 6 is a side view of the semiconductor device 100 according to the first embodiment. FIG. 6 is a view of FIG. 5 viewed from a direction A. The semiconductor device 100 includes a high-frequency circuit 50, a mounting substrate 60, and a projection 62 provided on the mounting substrate 60. The projection 62 is fitted between the protrusions 16 of the high-frequency circuit 50. The projection 62 has a shape in accordance with a recess of the rear surface 12 of the substrate 10. An upper surface 63 of the projection 62 is a surface bonded to the rear surface 12 of the high-frequency circuit 50, that is, a portion where the conductive resin is applied. The mounting substrate 60 is also referred to as a die bonding substrate.

According to the semiconductor device 100 according to the present embodiment, it is possible to secure a large distance between the upper surface 63 of the projection 62 and the upper surface 11 of the substrate 10 of the high-frequency circuit 50. This can prevent soaking up of the conductive resin by the tweezers, or the like, and perform mounting with a high yield ratio. A height of the projection 62 is preferably longer than a dimension of the recess on the rear surface 12 of the high-frequency circuit 50 by approximately 50 μm. By this means, most of the conductive resin protruding outside the chip does not head to the distal end portion of the tweezers, or the like, and crawls on the mounting substrate 60 around the projection 62. It is therefore possible to sufficiently decrease a risk of the conductive resin crawling up to the upper surface of the chip.

FIG. 7 is a perspective view for explaining a configuration of a wafer 80 according to the first embodiment. FIG. 7 illustrates a state before the substrate 10 of the present embodiment is divided into chips. On the wafer 80, protrusions 81 and 82 that are thick portions of the wafer 80 are formed. The protrusion 81 corresponds to the protrusion 16 of the high-frequency circuit 50. A width of the protrusion 81 is, for example, 100 to 400 μm. The protrusion 82 is a dummy portion provided for the purpose of reinforcing strength and warpage of the wafer 80. A width of the protrusion 82 is, for example, 100 to 400 μm.

For example, in a case where the whole surface of the wafer is made thinner to equal to or less than 50 μm, warpage occurs in the wafer, and there is a possibility that the wafer cannot be fixed on a stage upon characteristic inspection in a wafer state. Further, there is a possibility that it becomes difficult to perform wafer dicing while pasting a tape on the wafer. Still further, if the wafer is fixed on a flat stage, or the like, in a state where the wafer is warped, there is a possibility that breakage or a crack may occur in the wafer, which may lead to degradation of a yield ratio. Further, to achieve a higher frequency such as a terahertz waveband exceeding 100 GHz and improve heat dissipation, there is a case where a thickness of the substrate is made equal to or less than 30 μm. To achieve this thickness of the substrate with the wafer having a diameter equal to or greater than 4 inches is further difficult, because breakage occurs upon handling of the wafer due to degradation of strength in addition to problems of crawling up of the conductive resin and wafer warpage.

In contrast, in the present embodiment, by providing a thick portion in a grid shape on the wafer 80, even if the wafer 80 is made thinner, it is possible to prevent warpage of the wafer 80 and degradation of strength. This can prevent degradation of a yield ratio due to breakage of the wafer, a wafer crack, or the like, in processes of characteristic inspection, dicing, and the like.

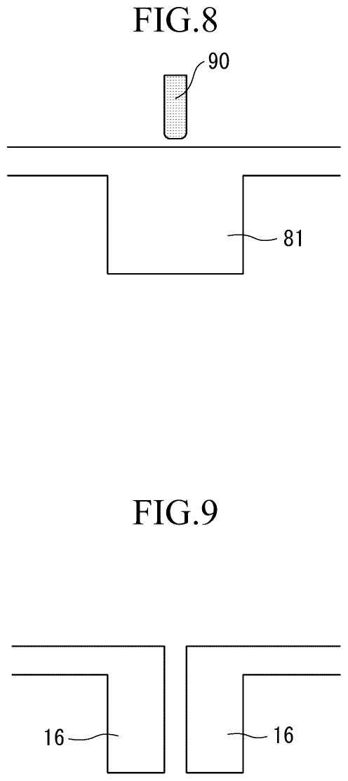

FIG. 8 is a view for explaining a state of the protrusion 81 of the wafer 80 according to the first embodiment before dicing. FIG. 9 is a view for explaining a state of the protrusion 81 of the wafer according to the first embodiment after dicing. In the dicing, a dimension corresponding to a width of a dicing blade 90 for cutting the wafer 80 is scraped off. A width of the protrusion 81 in the wafer state is approximately a total value of a width corresponding to two protrusions 16 after the dicing and the width of the dicing blade 90.

As a modification of the present embodiment, the substrate 10 may be formed with a material other than SiC. Further, the high-frequency circuit 50 is not limited to the MMIC and may be a matching circuit, a filter, or the like. A joint material that bonds the high-frequency circuit 50 and the projection 62 is not limited to the conductive resin and may be solder, or the like. Further, as will be described later in the embodiment, the protrusions 16 may be formed on other sides as well as the two facing sides of the substrate 10. In other words, the protrusions 16 only require to be formed at least along the two facing sides of the substrate 10.

These modifications can be applied, as appropriate, to high-frequency circuits and semiconductor devices according to the following embodiments. Note that the high-frequency circuits and the semiconductor devices according to the following embodiments are similar to those of the first embodiment in many respects, and thus differences between the high-frequency circuits and the semiconductor devices according to the following embodiments and those of the first embodiment will be mainly described below.

### Second Embodiment

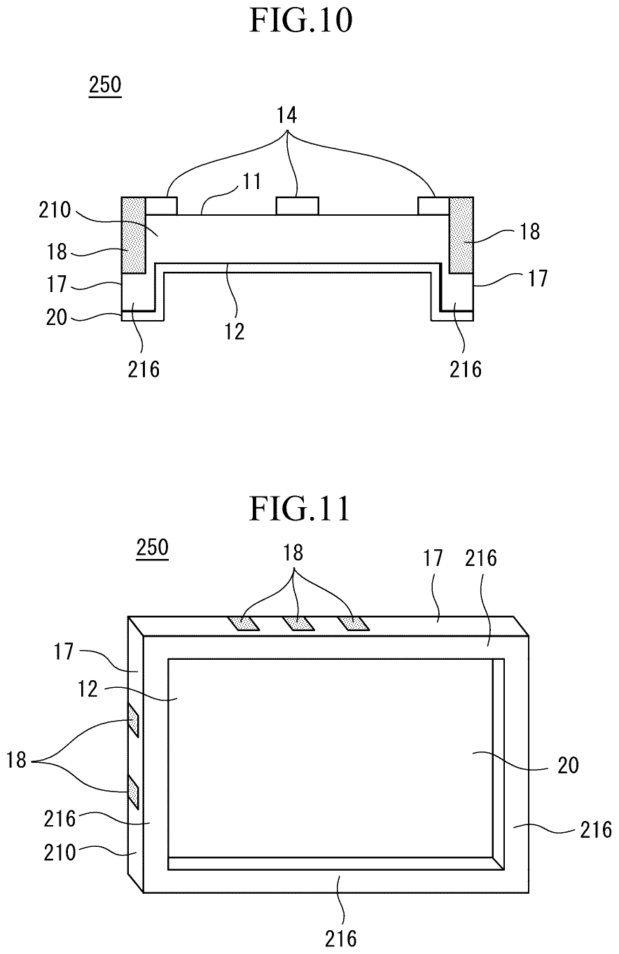

FIG. 10 is a cross-sectional view of a high-frequency circuit 250 according to a second embodiment. FIG. 11 is a view for explaining a configuration on a rear surface side of the high-frequency circuit 250 according to the second embodiment. In the present embodiment, a portion where a protrusion 216 is formed is different from that in the first embodiment. Other configurations are similar to the configurations of the first embodiment. In the present embodiment, in a peripheral portion on the rear surface 12 of a substrate 210, the protrusion 216 is formed along four sides of the substrate 210. In other words, a circular protrusion 216 is formed in the peripheral portion of the substrate 210.

Also in the present embodiment, a distance from a surface on which the conductive resin is applied to an upper surface of the substrate can be increased by the protrusion 216. Thus, a joint material can be prevented from crawling up to the upper surface of the substrate 210. It is therefore possible to make the high-frequency circuit 50 smaller by making the substrate 210 thinner and mount the high-frequency circuit 250 with a high yield ratio. Note that in the present embodiment, all the four sides of the peripheral portion of the substrate 210 are made thicker, and thus, spread of the conductive resin is confirmed by the conductive resin protruding outside of the substrate 210. The protruding conductive resin appears on the mounting substrate 60.

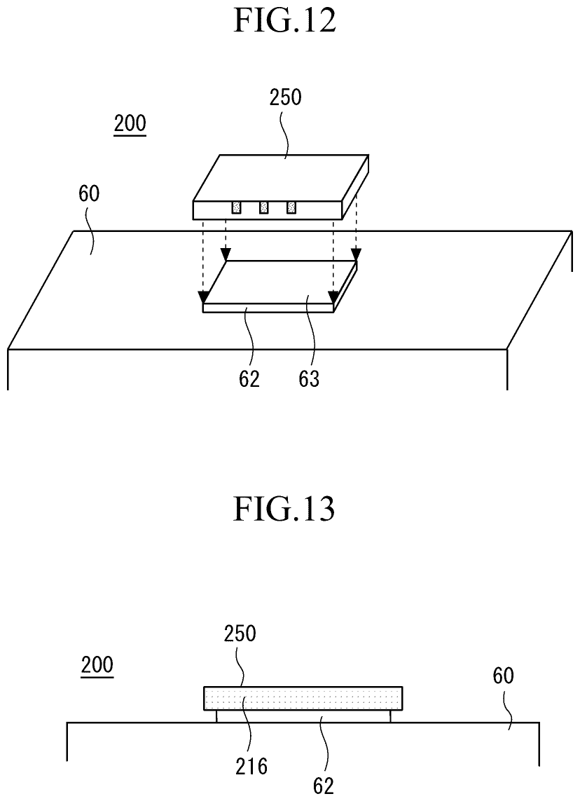

FIG. 12 is a perspective view for explaining a configuration of a semiconductor device 200 according to the second embodiment. FIG. 13 is a side view of the semiconductor device 200 according to the second embodiment. In the semiconductor device 200, the protrusion 216 provided along the four sides of the substrate 210 encloses the projection 62 on the mounting substrate 60. This makes it possible to position the high-frequency circuit 250 and improve position accuracy of mounting. Further, a direction in which the chip is to be grasped can be selected from two directions. Thus, even in a case where a direction in which the chip is to be grasped is restricted such as in a case where a mounting location is narrow, the effects of the present embodiment can be obtained.

In the present embodiment, the protrusion 216 is formed along the four sides of the substrate 210. Thus, both of the protrusions 81 and 82 on the wafer 80 illustrated in FIG. 7 form the protrusion 216.

### Third Embodiment

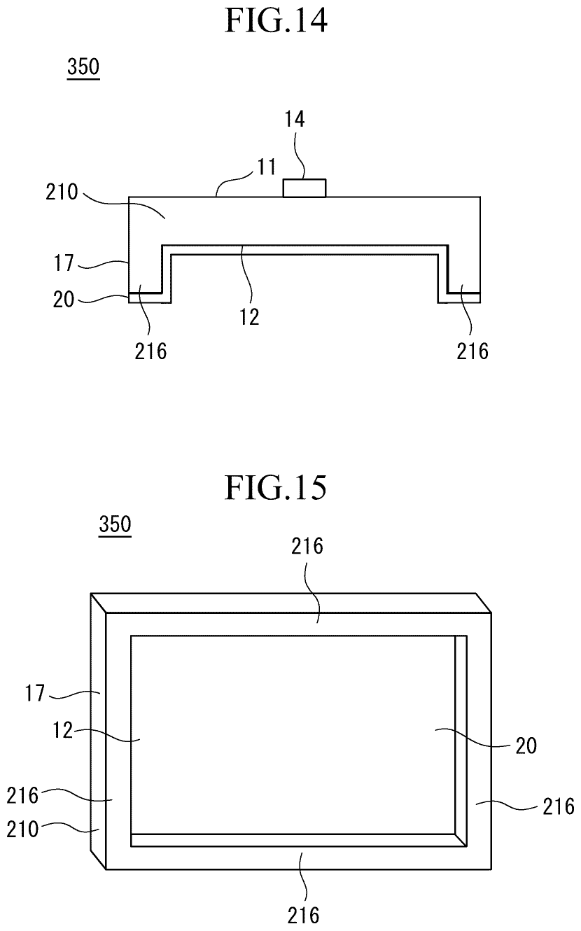

FIG. 14 is a cross-sectional view of a high-frequency circuit 350 according to a third embodiment. FIG. 15 is a view for explaining a configuration on a rear surface side of the high-frequency circuit 350 according to the third embodiment. The present embodiment is different from the second embodiment in that the pads 18 are not provided on the side surfaces of the substrate 210. Other configurations are similar to the configurations of the second embodiment. In such a case, the pad 18 is positioned on the upper surface 11 of the substrate 210. Even in a case where the pads 18 are not provided on the side surfaces 17, an effect of preventing crawling up of the resin is maintained.

Note that while in the present embodiment, an example has been described where the pads 18 provided on the side surfaces 17 of the substrate 210 of the second embodiment are removed, the pads 18 provided on the side surfaces 17 of the substrate 10 of the first embodiment may be removed.

### Fourth Embodiment

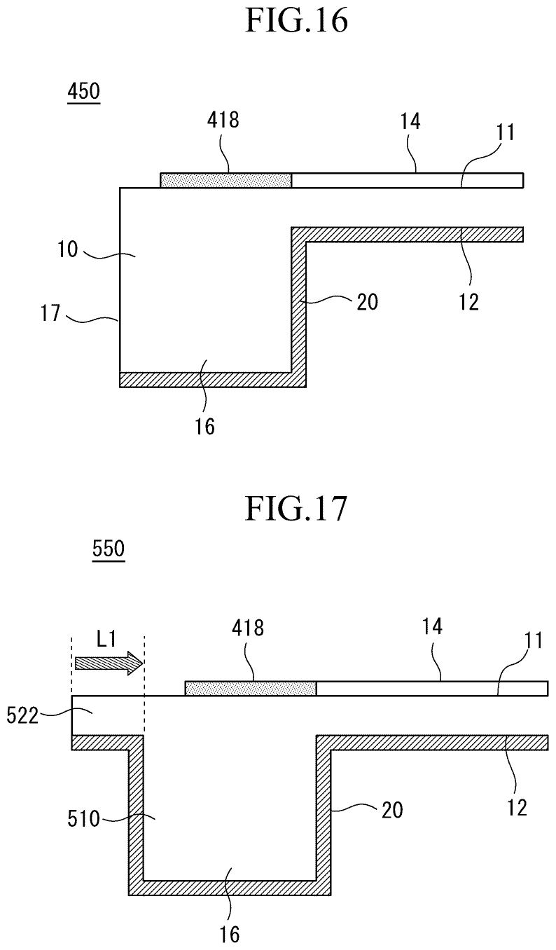

FIG. 16 is an enlarged view of a high-frequency circuit 450 according to a fourth embodiment. In the high-frequency circuit 450, an RF pad 418 is provided not on the side surface 17 of the substrate 10 but immediately above the protrusion 16. Other configurations are similar to the configurations of the first embodiment. This can reduce a capacity between the RF pad 418 and the conductor layer 20, so that it is possible to achieve improvement in accuracy of on-wafer measurement.

Further, in a case where the signal line 14 is replaced with a transistor in FIG. 16, the RF pad 418 serves as an electrode pad of the transistor. In this case, as a result of a pad capacity being reduced, it can be expected to improve performance of the transistor. Note that the pads may be provided both on the side surface 17 of the substrate 10 and immediately above the protrusion 16.

### Fifth Embodiment

FIG. 17 is an enlarged view of a high-frequency circuit 550 according to a fifth embodiment. In the high-frequency circuit 550, the protrusion 16 is formed on an inner side from an outermost peripheral portion on the rear surface 12 of a substrate 510. In other words, the substrate 510 has an internal setback 522 which is made thinner, on an outer side from the protrusion 16. The internal setback 522 is a portion indicated by a length L1 in FIG. 17. Other configurations are similar to the configurations of the fourth embodiment.

According to the present embodiment, it is possible to make the substrate 510 thinner in a portion cut by dicing. It is therefore possible to easily implement dicing. Further, a distance from the distal end portion of the tweezers, the collet, or the like, to the surface on which the conductive resin is applied can be further increased. It is therefore possible to further prevent crawling up of the conductive resin.

### Sixth Embodiment

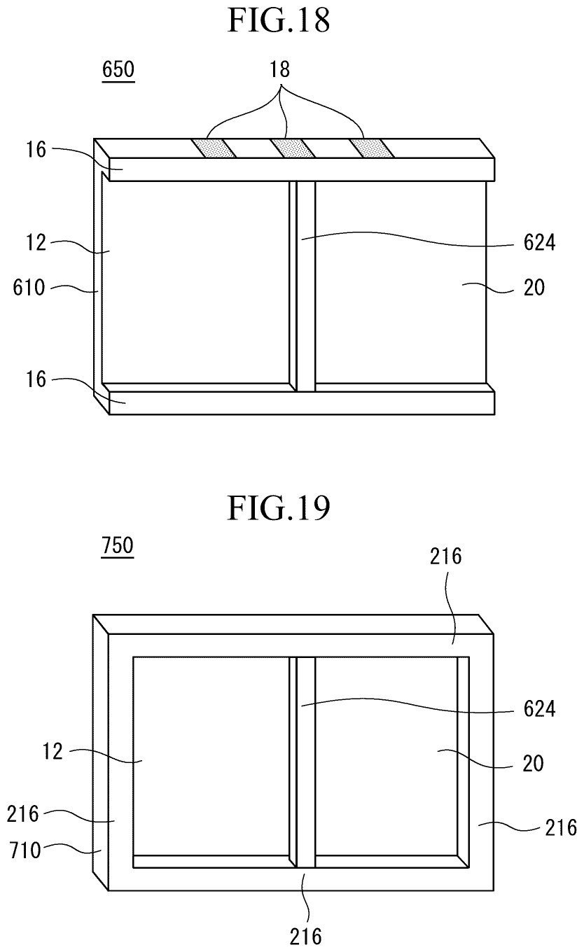

FIG. 18 is a view for explaining a configuration on a rear surface side of a high-frequency circuit 650 according to a sixth embodiment. In the high-frequency circuit 650, a protrusion 624 is further formed in a central portion on the rear surface 12 of a substrate 610. Other configurations are similar to the configurations of the first embodiment. The protrusion 624, for example, extends from one protrusion 16 to the other protrusion 16 in the central portion in a longitudinal direction of the substrate 610.

In the present embodiment, an effect of preventing warpage of the wafer can be improved. According to the present embodiment, particularly in a case where a thinned region is large, degradation of strength of the chip can be prevented. Further, in a case where an aspect ratio of vertical and horizontal dimensions of the chip is high, by forming the protrusion 624 in the middle of the long side of the chip, degradation of strength of the chip can be prevented.

FIG. 19 is a view for explaining a configuration on a rear surface side of a high-frequency circuit 750 according to a modification of the sixth embodiment. In the high-frequency circuit 750, the protrusion 624 is formed in the central portion on the rear surface 12 of a substrate 710. In this manner, the protrusion 624 in the present embodiment may be combined with the protrusion 216 in the second embodiment as well as the protrusion 16 in the first embodiment.

### Seventh Embodiment

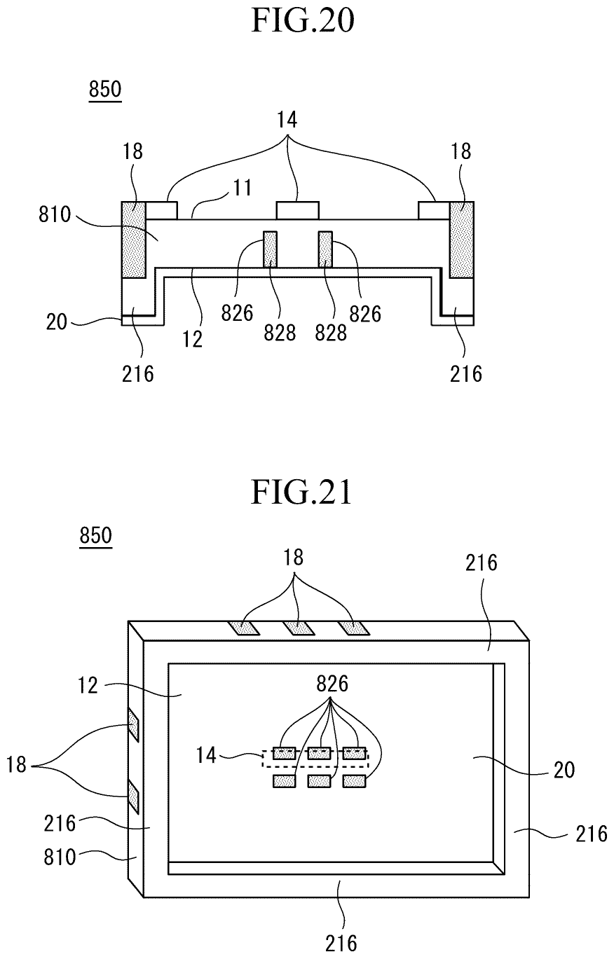

FIG. 20 is a cross-sectional view of a high-frequency circuit 850 according to a seventh embodiment. FIG. 21 is a view for explaining a configuration on a rear surface side of the high-frequency circuit 850 according to the seventh embodiment. In the high-frequency circuit 850, a hole 826 is formed immediately below an edge portion of the signal line 14 in the rear surface 12 of the substrate 810. The hole 826 is filled with a metal 828. Other configurations are similar to the configurations of the second embodiment. The hole 826 has, for example, a diameter of 15 μm. A plurality of holes 826 are formed at intervals of approximately 35 μm.

The substrates according to the first to the sixth embodiments are made sufficiently thinner in a portion other than the peripheral portion. In the present embodiment, further, the substrate 810 is engraved by forming the hole 826 immediately below the edge portion of the signal line 14 in which an electric field concentrates in the microstrip line. This can further increase a capacity between the substrate 810 and the signal line 14 and makes it possible to use a low-characteristics impedance line as a matching circuit. For example, in a case of a SiC substrate in a 100 GHz band, a ¼ wavelength is approximately 250 μm. In this event, by positioning equal to or less than five pairs, that is, 10 holes 826, a matching circuit using an ultra-low impedance microstrip line having a ¼ wavelength can be implemented.

Here, while the hole 826 filled with the metal 828 is positioned, characteristic impedance can be also adjusted by the hole 826 not filled with the metal 828. Note that the hole 826 may be formed in the substrate 10 in the first embodiment as well as the second embodiment.

Note that the technical features described in the above embodiments may be combined as appropriate.

### REFERENCE SIGNS LIST

10, 10a, 10b substrate, 11 upper surface, 12 rear surface, 14 signal line, 16 protrusion, 17 side surface, 18 pad, 20 conductor layer, 50, 50a, 50b high-frequency circuit, 60 mounting substrate, 62 projection, 63 upper surface, 80 wafer, 81, 82 protrusion, 90 dicing blade, 100, 200 semiconductor device, 210 substrate, 216 protrusion, 250 high-frequency circuit, 350 high-frequency circuit, 418 RFpad, 450 high-frequency circuit, 510 substrate, 550 high-frequency circuit, 610 substrate, 624 protrusion, 650 high-frequency circuit, 710 substrate, 750 high-frequency circuit, 810 substrate, 826 hole, 828 metal, 850 high-frequency circuit

1. A high-frequency circuit comprising:
a substrate; and
a signal line provided on an upper surface of the substrate, wherein
first protrusions are formed at least along two facing sides of the substrate in a peripheral portion on a rear surface opposite to the upper surface of the substrate, and
the first protrusions are formed on an inner side from an outermost peripheral portion on the rear surface of the substrate.

2. The high-frequency circuit according to claim 1, comprising pads provided on side surfaces corresponding to the two sides of the substrate.

3. The high-frequency circuit according to claim 1, wherein protrusions are not formed along two sides other than the two facing sides of the substrate in the peripheral portion on the rear surface of the substrate.

4. The high-frequency circuit according to claim 1, wherein protrusions are formed along four sides of the substrate in the peripheral portion on the rear surface of the substrate.

5. The high-frequency circuit according to claim 1, comprising a RF pad provided immediately above the first protrusions.

6. (canceled)

7. A high-frequency circuit comprising:
a substrate; and
a signal line provided on an upper surface of the substrate, wherein
first protrusions are formed at least along two facing sides of the substrate in a peripheral portion on a rear surface opposite to the upper surface of the substrate, and
a second protrusion is formed in a central portion on the rear surface of the substrate.

8. The high-frequency circuit according to claim 1, wherein a hole is formed immediately below an edge portion of the signal line in the rear surface of the substrate.

9. The high-frequency circuit according to claim 8, wherein the hole is filled with a metal.

10. A semiconductor device comprising:
the high-frequency circuit including a substrate and a signal line provided on an upper surface of the substrate, wherein first protrusions are formed at least along two facing sides of the substrate in a peripheral portion on a rear surface opposite to the upper surface of the substrate;
a mounting substrate; and
a projection provided on the mounting substrate and to be fitted between the first protrusions of the high-frequency circuit.
